(19) United States
(12) Patent Application Publication
(10) Pub. No.: US 2009/0168563 A1
(43) Pub. Date: Jul. 2, 2009

(54) Apparatus, system, and method for bitwise deskewing

(76) Inventor: Yueming Jiang, Rancho Cordova, CA (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/003,703

(22) Filed: Dec. 31, 2007

(51) Int. Cl. G11C 7/22; H03L 7/00

(52) U.S. Cl. 365/193; 365/194; 327/161

(57) ABSTRACT

A system and method for bitwise deskew. A DQS timing is used as reference, the delays of a plurality of transmission wires are calibrated with reference to a DQS line timing. Other embodiments are described and claimed.

### BACKGROUND OF THE INVENTION

Demands placed on computerized systems are continuously increasing. Such demands may test the limits of system capacities in terms of, for example, central processing unit (CPU) speed, memory capacity and/or memory and memory interfaces speed. Internal clock frequencies of microprocessors and/or CPUs have now crossed the GHz boundary. Moreover, multiple CPU systems are now common in the industry.

The above described trends may affect many components of a computerized system, in particular, memory chips. Timing margins of memory sub-systems, such as double data rate (DDR) interface are shrinking quickly as the double data rate 3 (DDR3) and its extensions push beyond 1600 Mega Transactions/second (MTs) and double data rate 4 (DDR4) reach 2400 Mega Transactions/second.

One of the problems encountered when designing and implementing high speed interfaces is skew. In the context of data interface buses, skew may be described as the inconsistency of signal timing or phase across multiple lines of a communication and/or interface bus. Such inconsistency may result from differences in length, routing and/or resistance of wires comprising a communication and/or interface bus. Skew may generally be observed, for example, when data is communicated from a memory towards a memory controller hub (MCH), and/or within a MCH, for example, due to different circuitry comprising the paths of different wires. In the presence of skew, data integrity may be jeopardized.

Deskew, as known in the art, is the elimination or reduction of skew. Busses and/or interfaces typically employ byte lane deskew. Byte lane deskew assumes that skew within a byte is negligible and consequently employs skew counter-measures aimed at synchronizing bundles of eight (8) wires with other bundles of eight (8) wires, rather than synchronizing single wires with one another.

DQ lanes and DQ strobe (DQS) are typically matched within 100 mils, which translates into about 20 picoseconds (ps), a relatively small number. However, the total mismatch between the DQ lanes also includes the delay mismatch from the DQ pads to the latches. For the read path, the 6σ mismatch among eight DQ paths is estimated to be 7% to 10% of nominal path delay (about 1 unit interval (UI) for DDR3). So, the total delay mismatch, around 0.1*UI, becomes fairly large compared to the timing budget at high data rates.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features and advantages thereof, may best be understood by reference to the following detailed description when read with the accompanied drawings in which:

FIG. 1 shows a schematic block diagram of a memory interface sub-system according to embodiments of the invention;

FIG. 2A shows a schematic block diagram of a bit lane according to embodiments of the invention;

FIG. 2B schematically illustrates a block diagram of a controllable delay cell according to embodiments of the invention;

FIG. 2C schematically illustrates a signal delay according to embodiments of the invention;

FIG. 3 schematically illustrates a flowchart according to embodiments of the invention;

FIG. 4A schematically illustrates respective phases of DQ and DQS lines according to embodiments of the invention; and

FIG. 4B schematically illustrates respective phases of DQ and DQS lines according to embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF EMBODIMENTS OF THE INVENTION

In the following detailed description, numerous specific details are set forth in order to provide a thorough understanding of embodiments of the invention. However it will be understood by those of ordinary skill in the art that the embodiments of the invention may be practiced without these specific details. In other instances, well-known methods, procedures, components and circuits have not been described in detail so as not to obscure the embodiments of the invention.

Some portions of the detailed description which follow are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as “processing.” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. This apparatus may be specially constructed for the desired purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a computer system bus.

The processes and displays presented herein are not inherently related to any particular computer or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein.

Unless explicitly stated, the method embodiments described herein are not constrained to a particular order or sequence. Additionally, some of the described method embodiments or elements thereof can occur or be performed at the same point in time.

According to embodiments of the invention, bit lane deskew may reduce or eliminate skew between distinct wires rather than skew between bundles of wires.

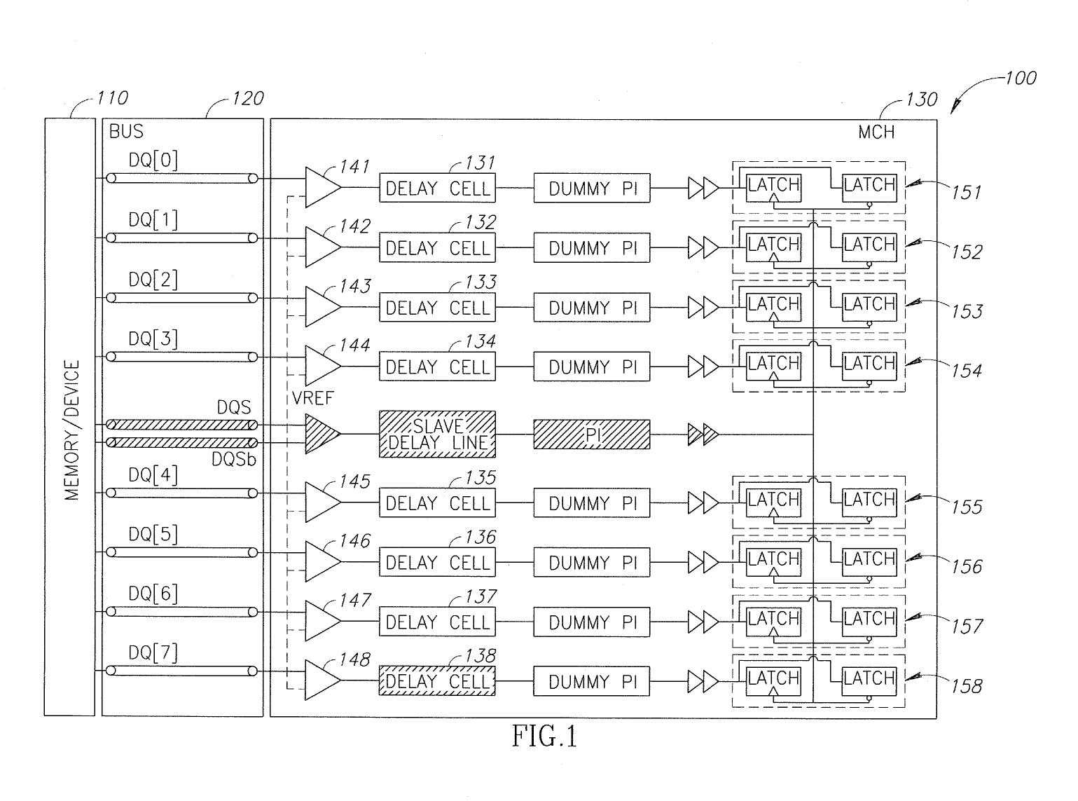

Reference is made to FIG. 1, showing an exemplary memory and memory interface sub-system according to embodiments of the invention. FIG. 1 shows memory 110, bus 120 memory controller hub (MCH) 130 comprising input circuits 141 to 148, output circuits 151 to 158 and delay cells 131 to 138. Memory 110 may be a double data rate (DDR) memory such as, but not limited to, DDR3 or DDR4. Alternatively, memory 110 may be replaced by any suitable memory or device such as, but not limited to random access memory (RAM), electrically erasable programmable read-only memory (EEPROM), hard drive, removable media, universal serial bus (USB) device, network storage device, network interface device, or FLASH storage device. Such alternatives may be made without departing from the scope of the invention.

According to embodiments of the invention, interface bus 120 may comprise any suitable number of wires. For example, bus 120 may comprise eight (8) data wires as shown by DQ[0] to DQ[7]. Alternatively, bus 120 may comprise, for example 16, 32 or 64 data wires. Bus 120 may further comprise strobe wires as shown by DQS and DQSb. According to embodiments of the invention, interface bus 120 may be, for example, an integrated drive electronics (IDE) bus, an advanced technology attachment (ATA) bus, serial advanced technology attachment (SATA) bus, small computer system interface (SCSI) bus, extended industry standard architecture (EISA) bus, video electronics standards association (VESA) bus or any other suitable bus, possibly in accordance with a connected device.

According to embodiments of the invention, memory controller hub (MCH) 130 may provide the system bus interface, memory controller, accelerated graphics port (AGP) interface, and hub interface for input/output (I/O). According to embodiments of the invention, input circuits 141 to 148 may perform any functionality that may be required in association with input signals. For example, input circuits 141 to 148 may attenuate, amplify or invert input signals. According to embodiments of the invention, input circuits 141 to 148 may comprise active and/or passive components, for example, logic gates, buffers, switches, latches, or any other suitable input circuit. According to embodiments of the invention, output circuits 151 to 158 may perform any functionality that may be required in association with output signals. For example, output circuits 151 to 158 may attenuate, amplify or invert output signals. According to embodiments of the invention, output circuits 151 to 158 may comprise active and/or passive components, for example, logic gates, buffers, switches, latches, or any other suitable output circuit. According to embodiments of the invention, delay cells 131 to 138 may delay a signal passing through them as described below.

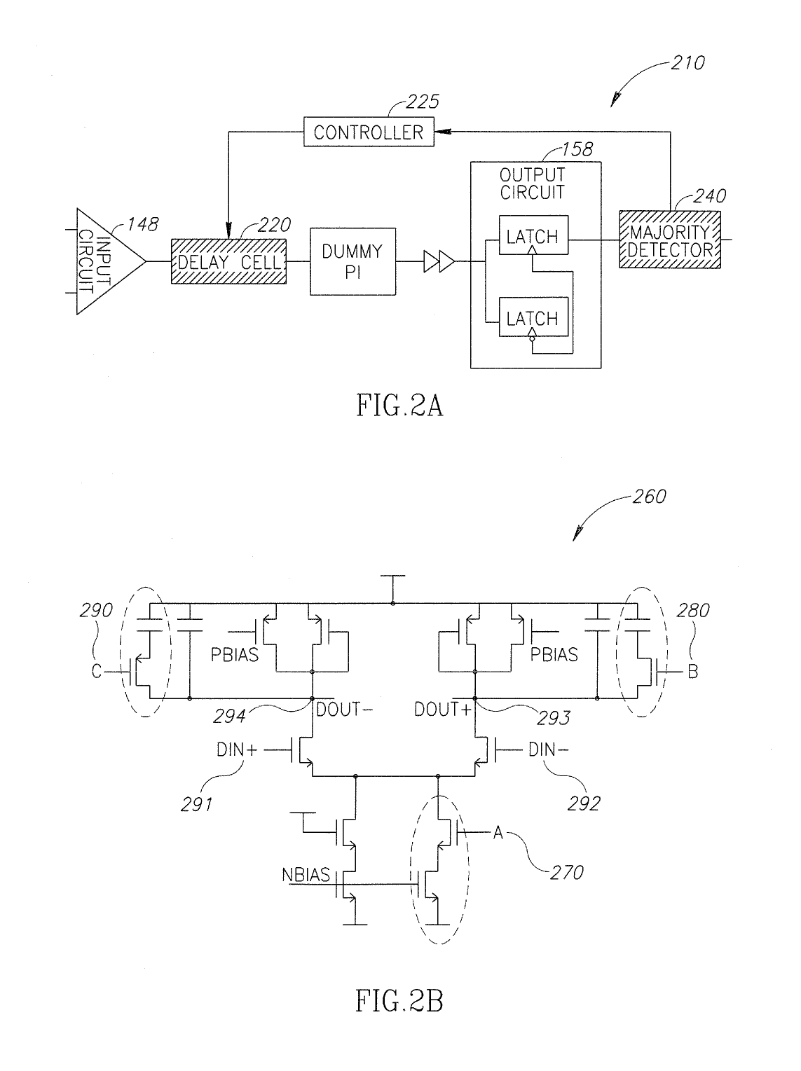

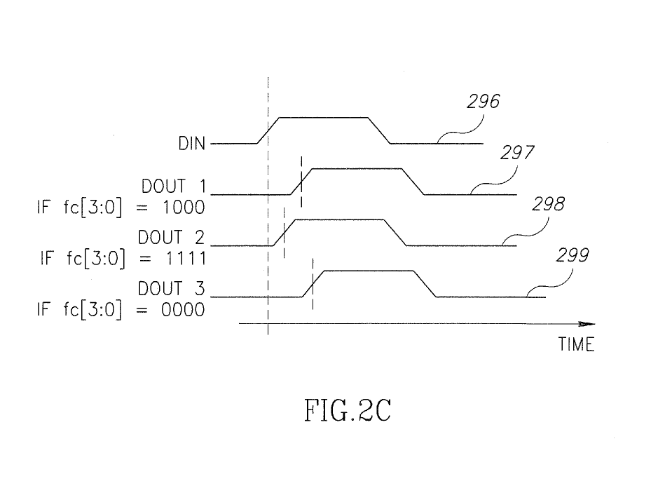

Reference is made to FIG. 2A showing an exemplary circuit 210 that may terminate a receive (RX) wire of bus 120 in accordance with embodiments of the invention. According to embodiments of the invention, input circuit 148 may apply required alterations, stabilization or modifications to an input signal as described above and output circuit 158 may apply required alterations, stabilization, time and/or phase synchronization or modifications to an output signal as described above. According to embodiments of the invention, delay cell 220 may be a controllable delay circuit. Such circuit may introduce delay to a signal passing through it. Delay cell 220 may further be configurable, for example, to enable adjusting the amount of delay introduced by delay cell 220. According to embodiments of the invention, delay cell 220 may be controlled and/or configured digitally.

According to embodiments of the invention, a computer program may access delay cell 220 and alter its configuration parameters, for example, an introduced time delay may be altered in such fashion in accordance with deskewing parameters or requirements. According to other embodiments of the invention, controller 225 may control delay cell 220. According to other embodiments of the invention, controller 225 may be embedded in, or implemented as a circuit or chip, an application specific integrated circuit (ASIC), a field-programmable gate array (FPGA) or any other suitable hardware. According to embodiments of the invention, controller 225 may control delay cell 220 according to input received from majority detector 240. According to embodiments of the invention, majority detector 240 may be used in order to sample and/or verify an output signal, for example, as described further below. According to embodiments of the invention, majority detector 240 may additionally be used in order to aid the verification of the output signal by filtering out noise.

It will be noted that although a single delay cell is shown in FIG. 2A, embodiments of the invention are not limited in this respect. According to embodiments of the invention, a bit lane path may include multiple delay cells such as, for example, delay cell 220. According to embodiments of the invention, multiple delay cells may be deployed in a bit lane. For example, in order to achieve synchronization at multiple locations along the paths of multiple bit lanes, multiple delay cells may be incorporated in the relevant paths where required. It will be noted that alterations or permutations such as modifications, additions, or omissions may be made to circuit 210 without, departing from the scope of the invention. For example, circuit 210 may have more, fewer, or other components. Additionally, operations of circuit 210 may be performed using any suitable logic comprising software, hardware, other logic or any combinations of the preceding.

Reference is made to FIG. 2B showing an exemplary circuitry that, according to embodiments of the invention, may be used to implement delay cell 220. According to embodiments of the invention, a four (4) bit control word may be used to control delay cell 260. According to embodiments of the invention, bits comprising a control word may be routed to control inputs A, B and C as shown by 270, 280 and 290 respectively. For example, bits 0 and 1 of a control word may be routed to A as shown by 270 while bits 2 and 3 may be routed into both B and C as shown by 280 and 290 respectively. According to embodiments of the invention, an input signal to be delayed may be input into din+ and din− as shown by 291 and 292 respectively. According to embodiments of the invention, a delayed output signal may be read at dout+ and dout− as shown by 291 and 292 respectively. It will be noted that alterations or permutations such as modifications, additions, or omissions may be made to circuit 260 without departing from the scope of the invention. For example, circuit 260 may have more, fewer, or other components. Additionally, operations of circuit 260 may be performed using any suitable logic comprising software. hardware, other logic or any combinations of the preceding.

Reference is made to FIG. 2C showing exemplary delays that may be observed at output points 293 and 294 with respect to input at 291 and 292 of circuit 260. FIG. 2C shows input signal din as shown by 296 and output signals dout1, dout2 and dout3 shown by 297, 298 and 299 respectively. As shown, a control word value (binary) of 1000 input into A, B and C may produce a delayed signal as shown by 297 with respect to input signal 296. A control word value (binary) of 1111 may result a delayed signal with respect to input signal 296 as shown by 298, while a control word value (binary) of 0000 may result a delayed signal with respect to input signal 296 as shown by 299.

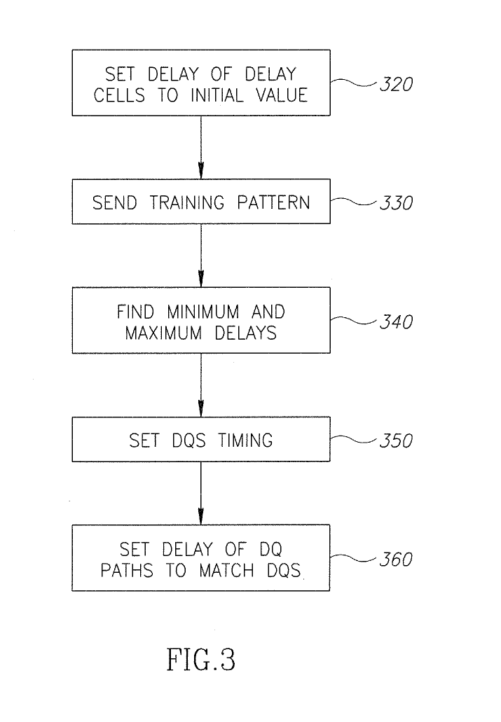

Reference is made to FIG. 3 showing a flow of an exemplary method for deskewing an interface bus according to embodiments of the invention. According to embodiments of the invention and as shown by block 320, the flow may include setting of delay cells (e.g. delay cells 131 to 138 of FIG. 1A) to an initial value. For example, all delay cells of all wires comprising a bus may be set to delay an incoming signal by 0.1 unit intervals (UIs). According to embodiments of the invention, setting all delay cells to an initial value greater than zero may enable applying negative delay to some paths by, for example, reducing the delay value of their associated delay cells while applying positive delay to other paths by, for example, increasing the delay value of their associated delay cells.

According to embodiments of the invention and as shown by block 330, the flow may include sending a training pattern, for example from memory 110 towards MCH 130. According to embodiments of the invention, a training pattern may be any suitable pattern, for example a pattern of 0101 may be used. According to embodiments of the invention, a training pattern may be sent simultaneously over all wires comprising an interface bus, for example, DQ[0] to DQ[7] in FIG. 1A.

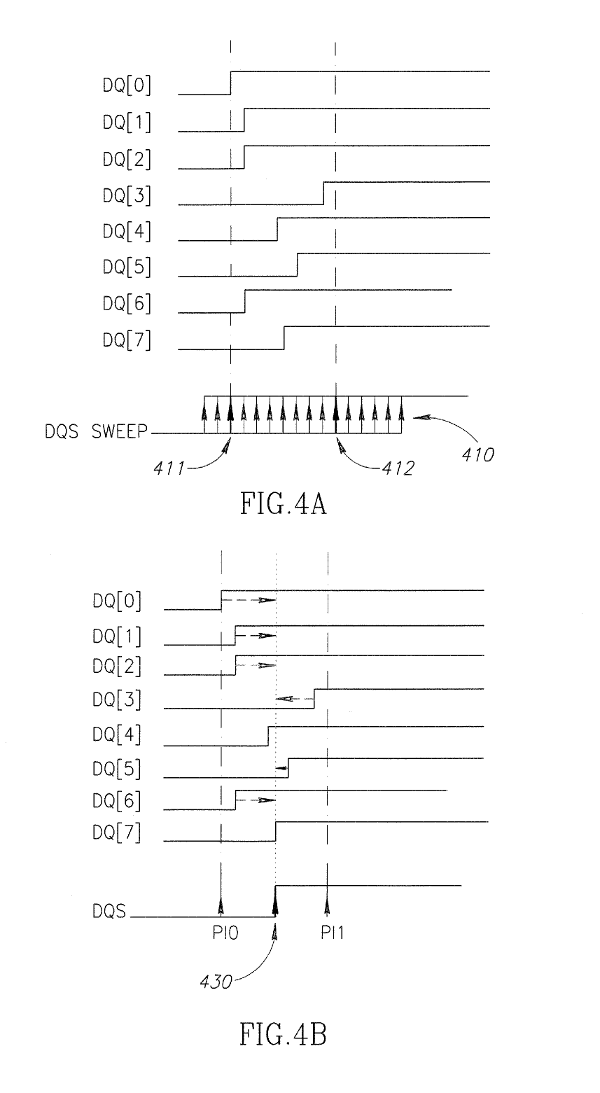

According to embodiments of the invention, the flow may include measuring transmission delays associated with the wires comprising an interface bus. According to embodiments of the invention and as shown by block 340, the flow may further include finding the highest and lowest delay associated with a plurality of wires comprising an interface bus. Reference is additionally made to FIG. 4A, which schematically illustrates a process for finding the lowest and highest delay associated with a set of conducting wires. According to embodiments of the invention and as shown by 410, a DQS line may be swept or periodically enabled through a period of time during which a training pattern as described above is being communicated by the relevant wires. Such period of time may be set so as to cover both the slowest data (e.g. DQ) line and the fastest line. According to embodiments of the invention, at each point where the DQS is enabled, majority detectors associated with the wires, (e.g. majority detector 240 in FIG. 2A), are examined and a vector comprising the values of all majority detectors is observed. According to embodiments of the invention and as shown by 411, the minimal delay may be determined as the point where the vector comprising all majority detectors assumes a value different than zero. For example, if eight wires comprise a bus under test then the value of the vector may be 00010000. At such point, at least one wire may have communicated the signal. Accordingly, such point may reflect the minimal delay.

According to embodiments of the invention and as shown by 412, the maximal delay may be determined as the point where the vector comprising all majority detectors assumes, for the first time, a value of all ones. For example if eight wires comprise a bus under test, then the value of the vector may be 1111111. At such point, all wires may have communicated the signal. Accordingly, such point may reflect the maximal delay.

According to embodiments of the invention, the flow may include calculating a corrective timing parameter. According to embodiments of the invention, a corrective timing parameter may be a timing or phase modification value that may be computed and further applied to the DQS timing or phase. For example, a corrective timing parameter may comprise a value and direction for modifying a timing parameter, for example a delay of 0.1 unit intervals or any other specified value of time or phase. According to embodiments of the invention and as shown by block 350, the flow may include adjusting a setting of the DQS timing (or phase). According to embodiments of the invention, the DQS timing (or phase) may be set to a value greater than the minimal delay measured for the wires comprising an associated interface bus and smaller than the maximal delay measured for the wires comprising an associated interface bus. For example, According to embodiments of the invention, a DQS timing (or phase) may be altered such that it aligns with a median of the measured delays. According to other embodiments of the invention, the DQS may be set to match an average, a weighted average, a mean, a midrange, or a mode associated with the delays measured.

According to embodiments of the invention and as shown by block 360, the flow may include calibrating the delay of the relevant paths to match the DQS timing (or phase). Reference is additionally made to FIG. 4B which schematically illustrates a timing (or phase) setting of a DQS line relative to the delays of paths of associated wires. According to embodiments of the invention and as shown by 430, a DQS timing, (or phase) may be set so that some of the signals (e.g. DQ[0], DQ[1], DQ[2] and DQ[6]) may need to be delayed in order to be aligned with the DQS while other signals (e.g. DQ[3] and DQ[5]) may need to be advanced in time, namely they require a negative delay. According to embodiments of the invention, a negative delay may be achieved by decreasing the initial delay that may have been set as shown by block 320. Note that some paths (e.g. DQ[7]) may align with the calibrated DQS and accordingly require no modification to their timing phase or delay setting.

According to embodiments of the invention, a logic module controlling the deskew process may alter the delay cells parameters according to output received from the associated majority detectors. For example, a controller, possibly implemented as a chip or ASIC, may be wired to the output of the majority detectors. According to embodiments of the invention, such controller may additionally be wired to the delay cells control inputs, e.g. 270, 280 and 290 as shown in FIG. 2B. According to embodiments of the invention, a controller wired as described may increase the delay associated with paths for which the associated majority detectors output a ‘1’ and decrease the delay for those paths for which the associated majority detectors output a ‘0’. Such iterative process may continue until all paths are calibrated into a range within a predefined variance corresponding to the DQS timing or phase.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the spirit of the invention.

What is claimed is:

1. An apparatus comprising:
a plurality of input circuits for receiving a respective plurality of input signals;
a plurality of controllable delay circuits respectively associated with said plurality of input circuits, wherein each of said controllable delay circuits is capable of producing a delay in transmitting said signal, said delay based, at least in part, on an input parameter provided to the controllable delay circuit; and
a plurality of output circuits respectively associated with outputs of said plurality of controllable delay circuits.

2. The apparatus of claim 1, further comprising a controller
to receive a plurality of output signals from said plurality of output circuits, and
to configure based at least in part on said output signals, said plurality of controllable delay circuits to synchronize the signals received at said plurality of output circuits.

3. The apparatus of claim 2, wherein said plurality of controllable delay circuits are controlled digitally.

4. The apparatus of claim 2, wherein at least some of said plurality of input circuits are each associated with a plurality of controllable delay circuits.

5. A system comprising:
the apparatus of claim 1; and
a communication interface bus connected to said plurality of input circuits.

6. The system of claim 5, wherein said communication interface bus is a memory interface bus.

7. The system of claim 6, further comprising a memory connected to said memory interface bus.

8. The system of claim 7, wherein said memory is a double data rate (DDR) memory.

9. The system of claim 5, further comprising a device connected to said communication interface bus wherein said device is selected from the group consisting of: a random access memory (RAM), an electrically erasable programmable read-only memory (EEPROM), an electronically erasable programmable read-only memory (E²PROM), a hard drive, a removable media, a universal serial bus (USB) device, a volatile storage chip, a read only memory (ROM), a dynamic RAM (DRAM), a synchronous DRAM (SD-RAM), a network storage device, an accelerated graphics port (AGP), an input/output (I/O) device, a network interface card, a FLASH storage device, and a peripheral component interconnect (PCI) compatible device.

10. A method comprising:
measuring a plurality of transmission delays associated with a respective plurality of data transmission paths;
calculating a corrective timing parameter based, at least in part, on plurality of transmission delay measurements;
modifying a timing parameter of a strobe associated with said plurality of data transmission paths according to said corrective timing parameter; and
adjusting a plurality of transmission delay parameters respectively associated with said plurality of data transmission paths based, at least in part, on said timing parameter and said transmission delay measurements.

11. The method of claim 10, wherein said measuring of said plurality of transmission delays comprises:
providing a predefined signal pattern to said plurality of data transmission paths; and
recording a state of a plurality of majority detectors respectively associated with said plurality of data transmission paths.

12. The method of claim 10, wherein calculating said corrective timing parameter comprises computing a parameter corresponding to said plurality of transmission delays, wherein said parameter is selected from a list consisting of:
an average, a weighted average, a mean, a midrange, a median and a mode.

13. The method of claim 10, wherein said adjusting a plurality of transmission delay parameters comprises reducing a delay associated with at least some of said plurality of data transmission paths.
